(19) United States
(12) Patent Application Publication
(10) Pub. No.: US 2012/0038844 A1
(43) Pub. Date: Feb. 16, 2012

(54) METHOD OF MANUFACTURING DISPLAY APPARATUS AND DISPLAY APPARATUS

(75) Inventors: Nakcho CHOI, Seoul (KR); Hee-Keun LEE, Suwon-si (KR); Haeju YUN, Incheon (KR)

(73) Assignee: SAMSUNG ELECTRONICS CO., LTD., Suwon-si (KR)

(21) Appl. No.: 13/197,934

(22) Filed: Aug. 4, 2011

(30) Foreign Application Priority Data
Aug. 10, 2010 (KR) 10-1010-0076974

(51) Int. Cl. G02F 1/1339; H01L 29/786; H01L 33/08; G02F 1/136

(52) U.S. Cl. 349/43; 257/59; 438/30; 257/E29.273; 257/E33.001

(57) ABSTRACT

A method for manufacturing a display apparatus includes preparing first and second substrates, forming a bonding spacer on the first substrate having a first height, forming a supporting spacer on the second substrate having a second height less than the first height, forming an image display part on one of the first substrate or the second substrate, and coupling the first substrate and the second substrate together until an upper surface of the supporting spacer contacts the first substrate and the second substrate is bonded to the bonding spacer.

This application claims priority to Korean Patent Application No. 10-2010-0076974, filed on Aug. 10, 2010, and all the benefits accruing therefrom under 35 U.S.C. §119, the content of which in its entirety is herein incorporated by reference.

### BACKGROUND OF THE INVENTION

(1) Field of the Invention

The present invention relates to a method of manufacturing a display apparatus and a display apparatus manufactured using the same.

(2) Description of the Related Art

A display apparatus, such as a liquid crystal display (“LCD”) and an electrophoretic display apparatus are widely used.

The display apparatus includes two substrates facing each other and an image display layer, e.g., a liquid crystal layer or an electrophoretic layer, disposed between the two substrates. The two substrates are coupled to each other and the two substrates are spaced apart from each other by a distance to dispose the image display layer therebetween.

A spacer is typically formed on one of the two substrates to maintain the distance between the two substrates, and an adhesive may be used to bond the spacer to the other substrate. A manufacturing process of the display apparatus may be complicated, thereby causing an increase of manufacturing costs and occurrence of defects based on the use of the adhesive.

### BRIEF SUMMARY OF THE INVENTION

The present invention obviates the above-mentioned problems by providing a method of manufacturing a display apparatus capable of simplifying a manufacturing process, to thereby reduce manufacturing cost and occurrence of defects.

The present invention further provides a display apparatus manufactured using the same.

According to an exemplary embodiment of the present invention, a method of manufacturing a display apparatus is provided. The method includes preparing a first substrate and a second substrate, forming a bonding spacer on the first substrate having a first height, and forming a supporting spacer on the second substrate having a second height less than the first height. An image display part is formed on one of the first substrate or the second substrate and the first substrate and the second substrate are coupled together until an upper surface of the supporting spacer contacts with the first substrate, and the second substrate is bonded to the bonding spacer.

According to an exemplary embodiment, the bonding spacer is formed by coating a resist on the first substrate, pre-baking the resist at a temperature of about 80° C. to about 100° C. during about 50 seconds to about 70 seconds, exposing the resist to a light, and developing the resist.

According to an exemplary embodiment, the bonding spacer may be a barrier.

According to an exemplary embodiment, the supporting spacer is formed by coating a resist on the second substrate, pre-baking the resist with a temperature of about 80° C. to about 100° C. during about 50 seconds to about 70 seconds, exposing the resist to a light, developing the resist, and post-baking the resist at a temperature of about 210° C. to about 240° C. during about 15 minutes to about 120 minutes.

According to an exemplary embodiment, a sealant may be formed along an end portion of one of the first substrate and the second substrate prior to pressing the first and second substrates.

According to an exemplary embodiment, the bonding spacer and the sealant may be post-baked at a temperature of about 100° C. to about 140° C. during about 15 minutes to about 120 minutes after the pressing of the first and second substrates.

According to another exemplary embodiment of the present invention, a display apparatus is provided. The display apparatus includes a first substrate, a second substrate facing the first substrate, a bonding spacer arranged on the first substrate. The bonding spacer to divides the first substrate into a plurality of areas, maintains a distance between the first substrate and the second substrate, and bonds the first substrate and the second substrate, and an image display part arranged in the plurality of areas between the first and second substrates.

According to an exemplary embodiment, the first substrate includes a first insulating substrate, a gate line formed on the first insulating substrate and extending in a first direction, a first insulating layer formed on the first insulating substrate on which the gate line is formed, a data line formed on the first insulating layer and crossing the gate line, a step-difference compensation pattern arranged on the first insulating layer between the gate line and the data line to compensate for a step-difference between the data line and the first insulating layer, and a switching element connected with the gate line and the data line.

According to an exemplary embodiment, the bonding spacer is overlapped with the data line and the step-difference compensation pattern.

According to another exemplary embodiment, the bonding spacer is overlapped with the gate line and the step-difference compensation pattern or is overlapped with the data line, the step-difference compensation pattern, and the gate line.

According to an exemplary embodiment, the image display part includes an image display layer which absorbs or reflects a light to display an image. The image display layer may be one of a liquid crystal layer, an electrophoretic layer, an electro-wetting layer, or an electrochromic layer. Further, the image display layer may be a cholesteric liquid crystal layer.

According to an exemplary embodiment of the present invention, the display apparatus may be manufactured without using an adhesive, and thus, a manufacturing process may be simplified, to thereby reduce manufacturing cost.

Further, the distance between the first and second substrates may be stably maintained by the bonding spacer without using an additional adhesive. Therefore, defects occurring in the image display part including the image display layer due to the use of adhesive may be prevented.

### BRIEF DESCRIPTION OF THE DRAWINGS

The above and other advantages of the present invention will become readily apparent by reference to the following detailed description when considered in conjunction with the accompanying drawings wherein:

FIG. 1 is a cross-sectional view illustrating an exemplary embodiment of a display apparatus according to the present invention;

FIG. 2 is a flowchart illustrating an exemplary embodiment of a method of manufacturing a display apparatus of FIG. 1 according to the present invention;

FIG. 3 is a cross-sectional view schematically illustrating an exemplary embodiment of a method of manufacturing a display apparatus of FIG. 1 according to the present invention;

FIG. 4 is a cross-sectional view schematically illustrating another exemplary embodiment of a method of manufacturing a display apparatus according to the present invention;

FIG. 5 is a cross-sectional view schematically illustrating another exemplary embodiment of a method of manufacturing a display apparatus of FIG. 4 according to the present invention;

FIG. 6 is a cross-sectional view schematically illustrating another exemplary embodiment of a method of manufacturing a display apparatus according to the present invention;

FIG. 7 is a cross-sectional view illustrating another exemplary embodiment of a display apparatus according to the present invention;

FIG. 8 is a flowchart illustrating another exemplary embodiment of a method of manufacturing a display apparatus according to the present invention;

FIG. 9 is a sectional view illustrating an exemplary embodiment of a coupling operation of a first substrate with a second substrate according to the present invention;

FIG. 10 is a plan view illustrating another exemplary embodiment of a display apparatus according to the present invention;

FIG. 11 is a cross-sectional view taken along line I-I′ of FIG. 10;

FIG. 12 is a plan view illustrating an exemplary embodiment of the pixel areas of FIG. 10 including a bonding spacer according to the present invention;

FIG. 13 is a plan view illustrating another exemplary embodiment of a display apparatus according to the present invention;

FIG. 14 is a plan view illustrating an exemplary embodiment of the pixel areas PA of FIG. 13 including a barrier according to the present invention;

FIG. 15 is a plan view illustrating another exemplary embodiment of a display apparatus according to the present invention;

FIG. 16 is a plan view illustrating another exemplary embodiment of a display apparatus according to the present invention;

FIG. 17 is a cross-sectional view illustrating an exemplary embodiment of a display apparatus including an electrophoretic layer as an image display layer according to the present invention;

FIG. 18 is a cross-sectional view illustrating an exemplary embodiment of a display apparatus including an electrochromic layer as an image display layer according to the present invention; and

FIG. 19 is a cross-sectional view illustrating an exemplary embodiment of a display apparatus including an electro-wetting layer as an image display layer according to the present invention.

### DETAILED DESCRIPTION OF THE INVENTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of he invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on,” another element, there are no intervening elements present. As used herein, the term “and/or” includes any and all combinations of one or more of the associated listed items.

It will be understood that, although the terms “first”, “second”, “third” etc. may be used herein to describe various elements, components, regions, layers and/or sections, these elements, components, regions, layers and/or sections should not be limited by these terms. These terms are only used to distinguish one element, component, region, layer or section from another region, layer or section. Thus, “a first element”, “component”, “region”, “layer” or “section” discussed below could be termed a second element, component, region, layer or section without departing from the teachings of the present invention.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms, “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, the present invention will be explained in detail with reference to the accompanying drawings.

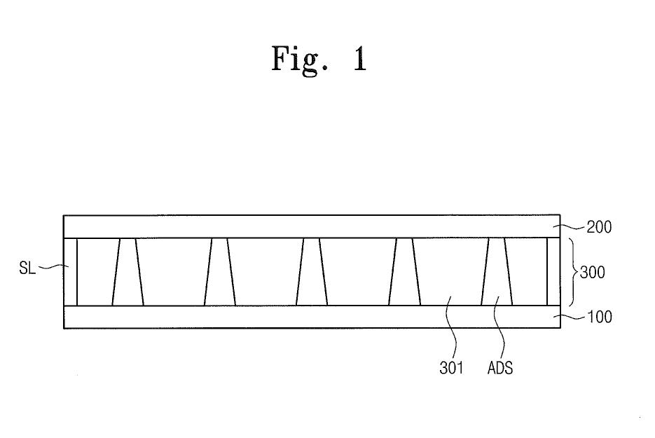

FIG. 1 is a cross-sectional view illustrating an exemplary embodiment of a display apparatus according to the present invention.

Referring to FIG. 1, a display apparatus according to an exemplary embodiment includes a first substrate 100, a second substrate 200, a bonding spacer ADS, an image display part 300, and a sealant SL.

According to an exemplary embodiment, the first substrate 100 includes a plurality of pixel areas PA and the second substrate 200 is arranged to face the first substrate 100.

According to an exemplary embodiment, the bonding spacer ADS maintains a distance between the first substrate 100 and the second substrate 200 and bonds the first substrate 100 to the second substrate 200. The bonding spacer ADS may be formed in various shapes. According to one exemplary embodiment, the bonding spacer ADS may be a column spacer.

According to an exemplary embodiment, the sealant SL is arranged along an end portion of the first and second substrates 100 and 200 to surround a space between the first and second substrates 100 and 200.

According to an exemplary embodiment, the image display part 300 is arranged in the space surrounded by the first substrate 100, the second substrate 200, and the sealant SL to display an image.

According to an exemplary embodiment, the image display part 300 includes an image display layer 301 absorbing or reflecting a light to display the image, and at least one electrode (not shown) applying an electric field to the image display layer 301. Although not shown in FIG. 1, the electrode may be formed on either the first substrate 100 or the second substrate 200. According to an exemplary embodiment, the image display layer 301 is a non-emissive display device, however, it is not particularly limited thereto. According to an exemplary embodiment, the image display layer 301 may be a liquid crystal layer, an electrophoretic layer, an electro-wetting layer, or an electrochromic layer. Further, the image display layer 301 may be a reflective-type image display layer. When the image display layer 301 is the reflective-type image display layer, the light provided from an exterior is visible to a user after being reflected by the image display layer 301. When the image display layer 301 is a transmissive-type image display layer, the light provided from a backlight included in the display apparatus is visible to a user after being transmitted through the image display layer 301. According to an exemplary embodiment, the reflective type display apparatus will now be described.

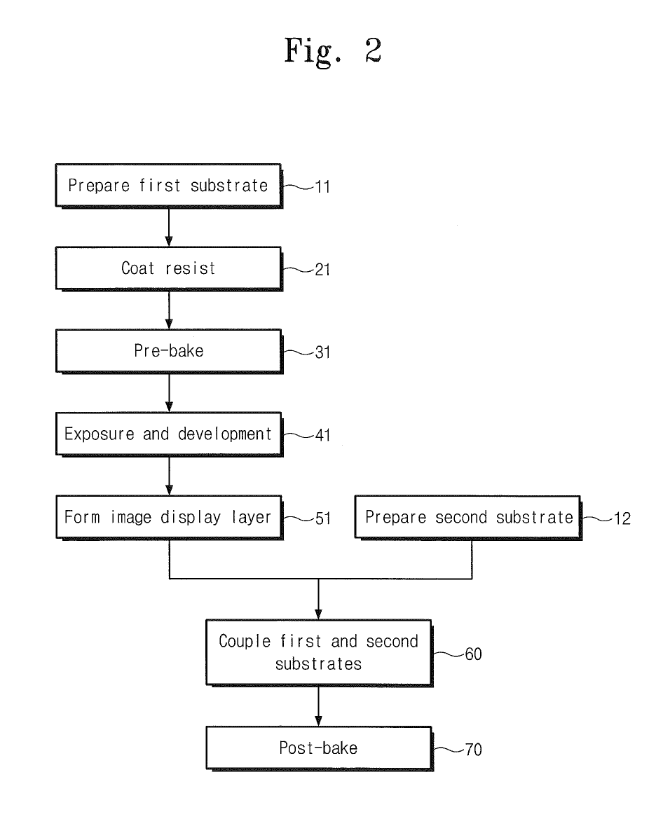

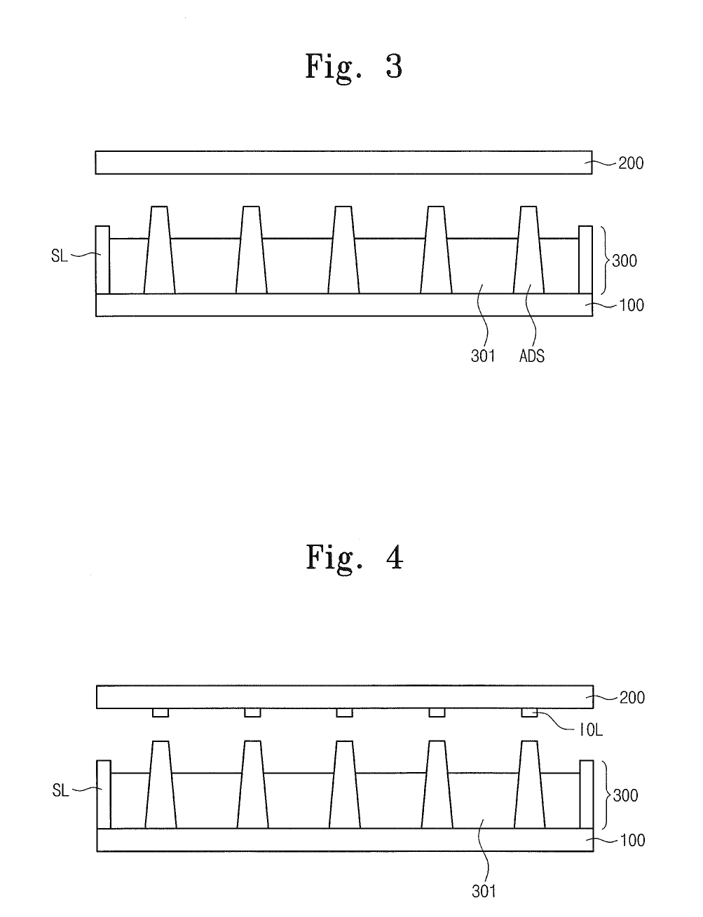

FIG. 2 is a flowchart illustrating an exemplary embodiment of a method of manufacturing the display apparatus of FIG. 1 and FIG. 3 is a cross-sectional view schematically illustrating an exemplary embodiment of a method of manufacturing the display apparatus of FIG. 1.

Referring to FIGS. 1 to 3, according to an exemplary embodiment, the method includes providing the first substrate 100 and the second substrate 200 separately at operations 11 and 12. After the first and second substrates are provided, the bonding spacer ADS is formed on the first substrate 100 at operations 21, 31 and 41 (described in detail below) and the image display layer 301 is formed on the first substrate 100 at operation 51. Next, the first substrate 100 and the second substrate 200 are coupled together at operation 60, and then the first and second substrates 100 and 200 are post-baked at operation 70.

As mentioned above, the first substrate 100 and the second substrate 200 are separately prepared at operations 11 and 12.

Then, according to an exemplary embodiment, bonding spacer ADS are formed on the first substrate 100. According to an exemplary embodiment, the bonding spacer ADS may be formed on either the first substrate 100 or the second substrate 200, or on both of the first and second substrates 100 and 200 such that the bonding spacer ADS formed on the first substrate 100 are not overlapped with the bonding spacer ADS formed on the second substrate 200 while coupling the first and second substrates 100 and 200 together. According to an exemplary embodiment, formation of the bonding spacer ADS formed on the first substrate 100 will now be described with reference to operations 21, 31 and 41 shown in FIG. 2. However, operations 21, 31 and 41 may also be performed to form the bonding spacer ADS on the second substrate 200.

At operation 21, the bonding spacer ADS is formed using a resist. According to an exemplary embodiment, the resist is a photosensitive organic polymer material, but the material should not be limited thereto. The resist may be various photosensitive polymers in which a photopolymerization reaction or a photodegradation reaction may occur.

The resist is then patterned through a photolithography process. As shown in FIGS. 1 to 3, according to an exemplary embodiment, each bonding spacer ADS has a trapezoidal shape, however, the shape of the bonding spacer ADS should not be limited thereto. That is, the bonding spacer ADS may be formed in other shapes (e.g., a rectangular shape) according to a condition of the photolithography process.

Hereinafter, the photolithography process will now be described. The resist in liquid form is coated on the first substrate 100 at operation 21. According to an exemplary embodiment, the resist may be coated using a spin coating method. The resist may have a thickness of about 2 micrometers to about 4 micrometers. The resist is pre-baked at a temperature of about 80° C. to about 100° C. during about 50 seconds to about 70 seconds at operation 31. According to an exemplary embodiment, the solvent inside the resist is partially volatilized during the pre-bake process, and thus, the resist is flexible and its viscosity is higher. However, the resist is not fully baked during this operation. Then, at operation 41, the pre-baked resist is exposed to a light (e.g., an ultraviolet ray) using a mask which has a pattern corresponding to the bonding spacer ADS and the resist is developed. As a result of the developing operation, the resist is patterned. The patterned resist may have a width of about 10 micrometers to about 30 micrometers.

A sealant SL is then formed on the first substrate 100. The sealant SL is formed along the end portion of the first substrate 100 to provide the space in which the image display layer 301 is formed.

Then, at operation 51, the image display layer 301 is formed on the first substrate 100 on which the sealant SL is formed. When the image display layer 301 is a fluid having a viscosity, the image display layer 301 may be formed through a one-drop filling (“ODF”) process or an inkjet process, which drips the fluid on the substrate.

Next at operation 60, the first substrate 100 on which the bonding spacer ADS is formed is arranged to face the second substrate 200, and at least one of the first substrate 100 or the second substrate 200 is coupled together e.g., by pressing. The bonding spacer ADS is bonded to the second substrate 200 as a result of the coupling.

The first substrate 100 and the second substrate 200 are then post-baked at a temperature of about 100° C. to about 140° C. during about 15 minutes to about 120 minutes (S70). The post-bake operation is performed to simultaneously bake the sealant SL and the bonding spacer ADS. When the post-bake operation is completed, the sealant SL and the bonding spacer ADS are fully baked. Since the bonding spacer ADS is fully baked while being bonded to the second substrate 200, the distance between the first and second substrates 100 and 200 may be stably maintained.

When a display apparatus is manufactured according to the above-described method, the distance between the first and second substrates 100 and 200 may be stably maintained as mentioned above, and in addition, the first and second substrates 100 and 200 may be bonded to each other without using additional adhesive. Therefore, defects in association with the use of an adhesive, for example, when an adhesive is mixed with the image display layer 301, may be reduced.

FIG. 4 is a cross-sectional view schematically illustrating another exemplary embodiment of a method of manufacturing a display apparatus according to the present invention.

The same reference numerals denote the same elements as in the exemplary embodiment shown in FIG. 3, and thus the detailed descriptions of the same elements will be omitted.

Referring to FIG. 4, an exemplary embodiment of a display apparatus according to the is provided with an inorganic layer IOL disposed between a bonding spacer ADS and a second substrate 200. Since the second substrate 200 includes a material, such as glass, quartz or silicon, the inorganic layer IOL is disposed between the second substrate 200 and the bonding spacer ADS to improve an adhesive property between the second substrate 200 and the bonding spacer ADS which includes an organic polymer. According to an exemplary embodiment, the inorganic layer IOL may include silicon nitride (SiNx).

The display apparatus according to this exemplary embodiment of the present invention is manufactured as follows. When first substrate 100 and the second substrate 200 are separately prepared at operations 11 and 12 shown in FIG. 2, the bonding spacer ADS and the sealant SL are formed on the first substrate 100 at operations 21, 31 and 41. Then, at operation 51, the image display layer 301 is formed on the first substrate 100 and the first substrate 100 and the second substrate 200 are coupled together. After that, the first and second substrates 100 and 200 are baked at operation 70.

However, in this exemplary embodiment, the inorganic layer IOL is formed on the second substrate 200 before the first and second substrates 100 and 200 are coupled together as shown in FIG. 4. The inorganic layer IOL is formed to correspond to the bonding spacer ADS such that the inorganic layer IOL may make contact with an upper surface of the bonding spacer ADS when the first and second substrates 100 and 200 are coupled together. According to an exemplary embodiment, the inorganic layer IOL may be formed by depositing an inorganic material such as silicon nitride on an insulating substrate and patterning the inorganic material through a photolithography process.

According to exemplary embodiments, the display apparatus may be manufactured using other methods.

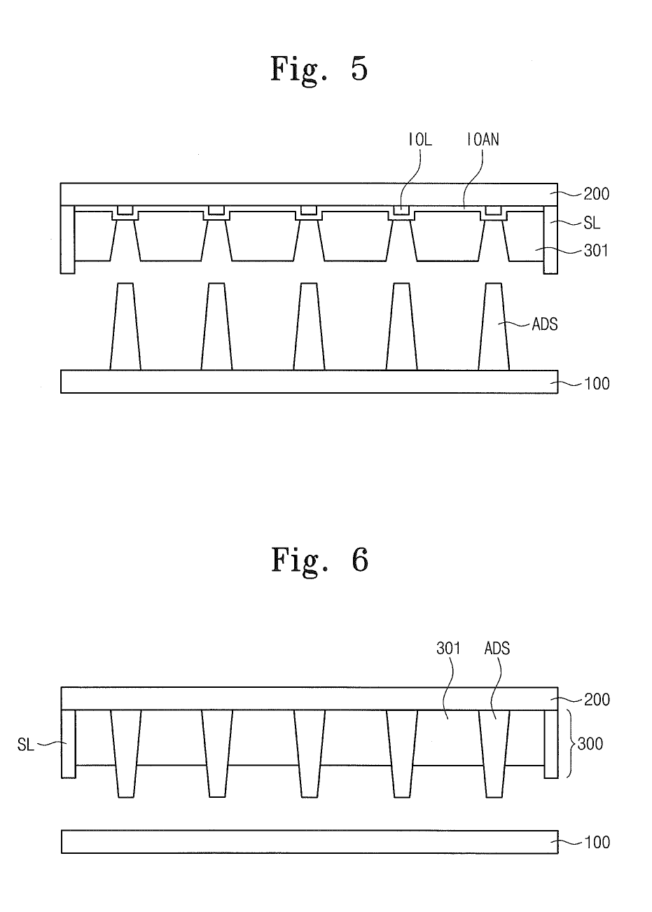

FIG. 5 is a cross-sectional view schematically illustrating another exemplary embodiment of a method of manufacturing the display apparatus of FIG. 4 according to the present invention.

As shown in FIG. 5, a first substrate 100 and a second substrate 200 are separately prepared and the bonding spacer ADS is formed on the first substrate 100.

Further, according to an exemplary embodiment, the inorganic layer IOL is formed on the second substrate 200. The inorganic layer IOL is formed to corresponding to the bonding spacers ADS when the first and second substrates 100 and 200 coupled together. An inorganic alignment layer IOAN may be formed on the second substrate 200 to cover the inorganic layer IOL. The inorganic alignment layer IOAN may include the inorganic material such as silicon nitride (SiNx) or silicon oxide (SiOx). The sealant SL is formed along the end portion of the second substrate 200. Then, the image display layer 301 is formed on the second substrate 200 on which the inorganic layer IOL, the inorganic alignment layer IOAN, and the sealant SL are formed. The first substrate 100 and the second substrate 200 are coupled together, and then the first and second substrates 100 and 200 are post-baked as described above to manufacture the display apparatus.

Since the image display layer 301 includes a liquid crystal layer, the inorganic alignment layer IOAN may align liquid crystal molecules of the liquid crystal layer and hold the liquid crystal molecules without spreading out the liquid crystal molecules. That is, the inorganic alignment layer IOAN is formed to change a surface energy of the second substrate 200, and thus a surface tension between the inorganic alignment layer IOAN and the liquid crystal layer increases to weaken spreadability of the image display layer 301. Therefore, according to an exemplary embodiment, the image display layer 301 may be arranged according to a pattern of the inorganic layer IOL. When the inorganic alignment layer IOAN is not formed, the liquid crystal layer may be formed to directly contact either a first electrode or a second electrode which will be described later. When the liquid crystal layer directly contacts the first electrode or the second electrode, the spreadability of the liquid crystal layer becomes higher than when the inorganic alignment layer IOAN exists. Thus, the liquid crystal layer may be formed using the inkjet method such that the liquid crystal layer may be formed in a predetermined area.

FIG. 6 is a cross-sectional view schematically illustrating another exemplary embodiment of a method of manufacturing a display apparatus according to the present invention.

Referring to FIG. 6, a display apparatus according to the an exemplary embodiment includes a second substrate 200 on which bonding spacer ADS, a sealant SL, and an image display layer 301 are formed. As mentioned above, a first substrate 100 and the second substrate 200 are separately prepared. Then, the bonding spacer ADS and the sealant SL are formed on the second substrate 200 and the image display layer 301 is formed on the second substrate 200. The first and second substrates 100 and 200 are coupled together, and the first and second substrates 100 and 200 are post-baked.

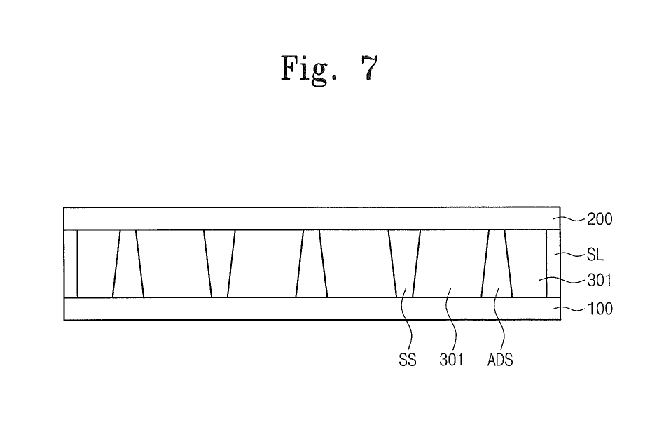

FIG. 7 is a cross-sectional view illustrating another exemplary embodiment of a display apparatus according to the present invention.

Referring to FIG. 7, a display apparatus according to an exemplary embodiment includes a first substrate 100, a second substrate 200, a bonding spacer ADS, a supporting spacer SS, an image display part 300, and a sealant SL.

According to an exemplary embodiment, the supporting spacer SS maintains a distance between the first and second substrates 100 and 200. Although the first substrate 100 and the second substrate 200 are coupled together before the bonding spacer ADS are not fully baked, the distance between the first and second substrates 100 and 200 may be uniformly maintained over the entire area of the first and second substrates 100 and 200 due to the use of the supporting spacer SS. The supporting spacer SS has a uniform height regardless of pressure applied when the supporting spacer SS is completely baked.

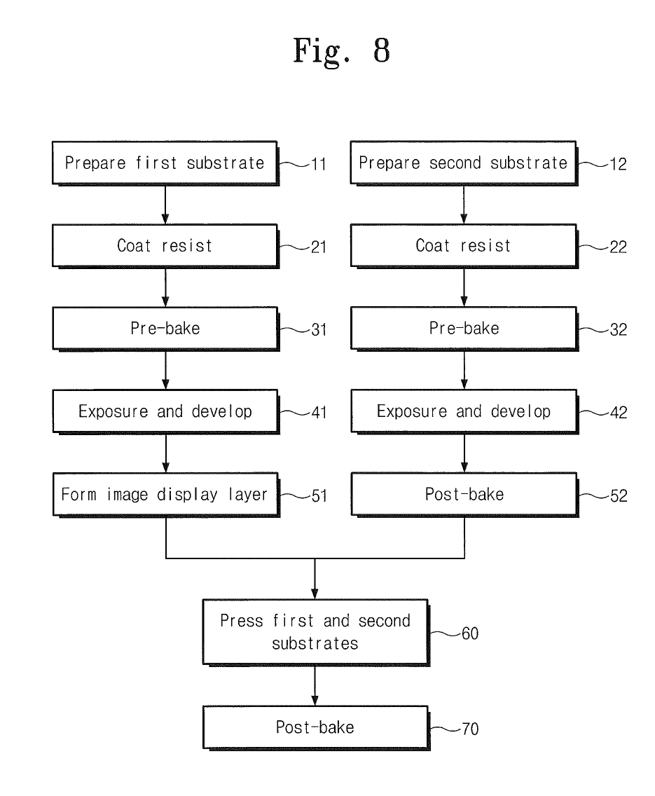

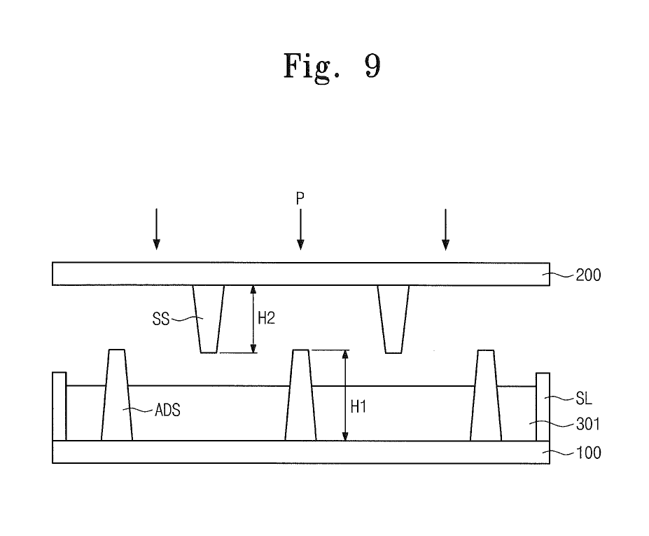

FIG. 8 is a flowchart illustrating an exemplary embodiment of a method of manufacturing a display apparatus according to the present invention. FIG. 9 is a sectional view illustrating an exemplary embodiment of a coupling operation the first substrate with the second substrate as shown in FIG. 7, according to the present invention.

Referring to FIG. 8, the method includes preparing the first substrate 100 and the second substrate 200 are separately at operations 11 and 12, and forming the bonding spacers ADS on either the first substrate 100 or the second substrate 200 (at operations 21, 31, and 41). The supporting spacer SS is formed on the first or second substrate 100 or 200 on which the bonding spacer ADS is not formed. According to this exemplary embodiment, the supporting spacer SS is formed on the second substrate 200 at operations 22, 32, 42, and 52 which are similar to operations 21, 31, 41 except a post-bake operation is performed at operation 52 (to be described later), and the image display layer 301 is formed on the first substrate 100 at operation 51. The first and second substrates 100 and 200 are coupled together, and the first and second substrates 100 and 200 are post-baked at operation 70.

Thus, as mentioned above, the first substrate 100 and the second substrate 200 are separately prepared at operations 11 and operation 12. Then, the bonding spacer ADS is formed on either the first substrate 100 or the second substrate 200 at operations 21, 31, and 41, and the supporting spacer SS is formed on the first or second substrate 100 or 200 on which the bonding spacer ADS is not formed. In this exemplary embodiment, the supporting spacer SS is formed on the second substrate 200 at operations 22, 32, 42, and 52. For explanation purposes, in this exemplary embodiment, a structure that the bonding spacer ADS is formed on the first substrate 100 and the supporting spacer SS is formed on the second substrate 200 will be described however, exemplary embodiments are not limited thereto.

The bonding spacer ADS is formed similar to the method described in FIG. 2.

Further, the supporting spacer SS may be formed using a resist similar to the bonding spacer ADS. According to an exemplary embodiment, the supporting spacer SS is formed to have a height less than that of the bonding spacer ADS. That is, the bonding spacer ADS has a first height H1 and the supporting spacer SS has a second height H2 such that the first height H1 is greater than the second height H2. The resist may be a photosensitive organic material and patterned through a photolithography process. Details regarding the photolithography process will now be described.

At operation 22, the resist in liquid form is coated on the first substrate 100. According to an exemplary embodiment, the resist may be coated using a spin coating method.

At operation 32, the resist is pre-baked at a temperature of about 80° C. to about 100° C. during about 50 seconds to about 70 seconds. The solvent inside the resist may be partially volatilized during the pre-bake operation, and thus, the resist is flexible and its viscosity is high. However, the resist is not fully baked through the pre-bake operation.

Then, at operation 42, the baked resist is exposed to the ultraviolet ray using a mask which has a pattern corresponding to the supporting spacer SS and the mask is formed in an area where the bonding spacer ADS is not formed such that the mask is not overlapped with the bonding spacer ADS when the first and second substrates 100 and 200 are coupled together. When the exposed resist is developed, the resist is patterned.

At operation 52, the patterned resist is post-baked at a temperature of about 210° C. to about 240° C. during about 15 minutes to about 120 minutes. After the post-bake process, the resist becomes the supporting spacer SS which is fully baked. Since the supporting spacer SS is fully baked through the post-bake operation, the supporting spacer SS has a relatively lower viscosity and elasticity than that of the bonding spacer ADS.

Although not shown in FIG. 8, according to an exemplary embodiment, the sealant SL may be formed on either the first substrate 100 or the second substrate 200. The sealant SL is formed along an end portion of the first substrate 100 or the second substrate 200 to provide a space in which the image display layer 301 is formed. In this exemplary embodiment, the sealant SL may be formed on the first substrate 100 however exemplary embodiments are not limited hereto.

Then, at operation 51, the image display layer 301 is formed on the first substrate 100 on which the sealant SL is formed. When the image display layer 301 is a fluid having a viscosity, the image display layer 301 may be formed through a one-drop filling (“ODF”) process or an inkjet process that drips the fluid on the substrate.

The first substrate 100 is placed to face the second substrate 200, and a pressure P is applied to at least one of the first substrate 100 or the second substrate 200 to couple the first substrate 100 to the second substrate 200. The first and second substrates 100 and 200 are pressed together until the distance between the first and second substrates 100 and 200 is equal to the second height H2.

Since the bonding spacer ADS is more flexible, the bonding spacer ADS may be pressed until the first height H1 of the bonding spacer ADS becomes equal to the second height H2. When the bonding spacer ADS is pressed, a contact area between the bonding spacer ADS and the second substrates 200 increases, and an adhesive property of the bonding spacer ADS may be improved by the pressure P. Thus, the bonding spacer ADS may be stably bonded to the second substrate 200. The supporting spacer SS has no flexibility after performing the post-bake process, thereby maintaining the second height H2 regardless of the pressure P. As a result, the distance between the first and second substrates 100 and 200 may be uniformly maintained over the entire area by the supporting spacer SS.

At operation 70, the first and second substrates 100 and 200 are post-baked at a temperature of about 100° to about 140° during about 15 minutes to about 120 minutes. The post-bake operation is performed to fully bake the sealant SL and the bonding spacer ADS.

According to the above-described method, the distance between the first and second substrates 100 and 200 may be stably maintained and the first and second substrates 100 and 200 may be bonded to each other without using an additional adhesive.

Further, according to an exemplary embodiment, the bonding spacer ADS may be used as a barrier to divide the image display layer 301 into a plurality of areas. Thus, no additional barrier is required to divide the image display layer 301, to thereby simplifying the manufacturing method.

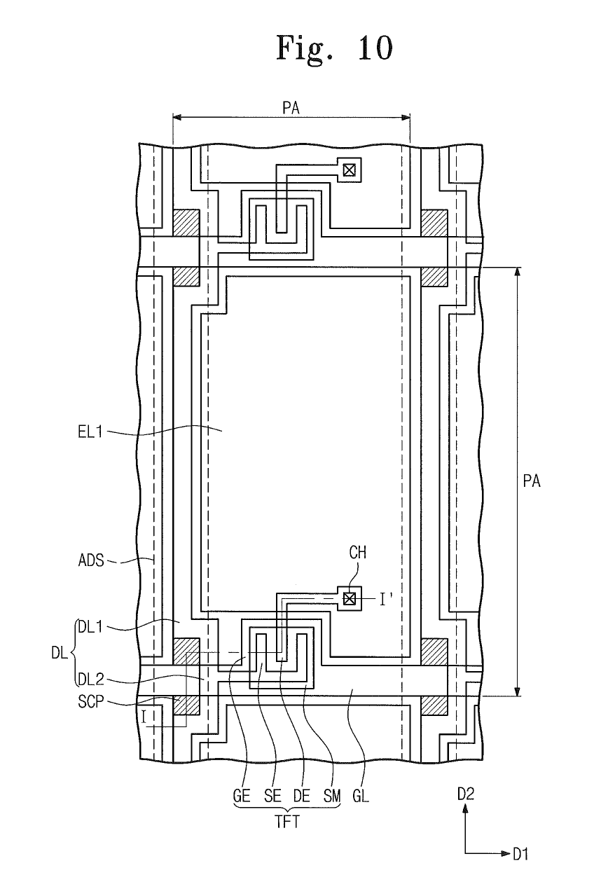

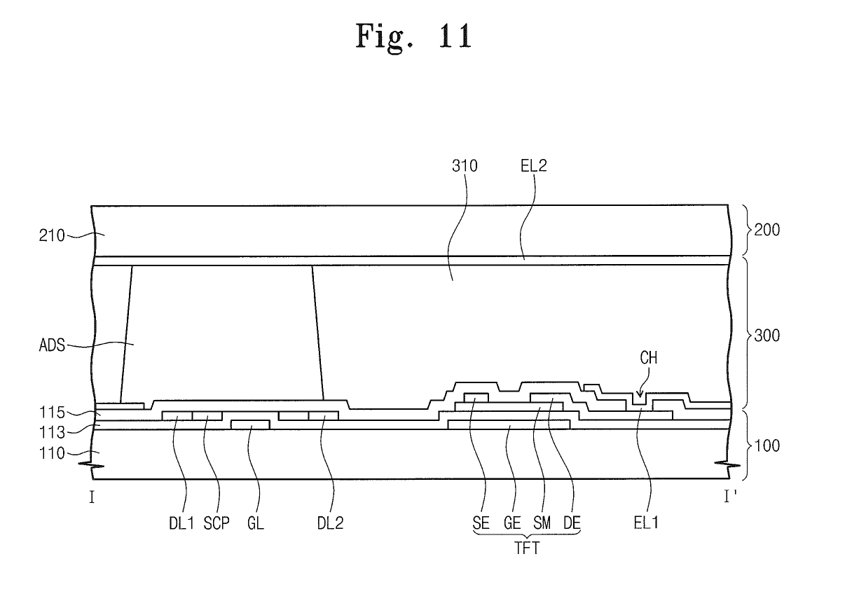

FIG. 10 is a plan view illustrating another exemplary embodiment of a display apparatus according to the present invention, and FIG. 11 is a cross-sectional view taken along line I-I′ of FIG. 10.

The display apparatus according to this exemplary embodiment is manufactured using the same method as shown in FIG. 2 and the bonding spacer ADS is used as a barrier instead of a column spacer. In addition, the display apparatus according to this exemplary embodiment includes a liquid crystal layer as the image display layer 301. The supporting spacer SS is omitted in this exemplary embodiment, however it should not be limited thereto. Thus, if the supporting spacer SS is included it may be formed using the same method as shown in FIG. 8.

Referring to FIGS. 10 and 11, according to an exemplary embodiment, the display apparatus includes a first substrate 100, a second substrate 200, a bonding spacer ADS, an image display part 300, and a sealant (not shown).

The display apparatus includes a plurality of pixel areas PA displaying an image and a non-pixel area formed along with an end portion of the display apparatus to surround the pixel areas. The sealant is arranged in the non-pixel area along with the end portions of the first substrate 100 or the second substrate 200 as shown in FIGS. 1 to 9.

In FIGS. 10 and 11, an exemplary embodiment of a pixel area PA is described for explanation purposes, however, the pixel areas PA are arranged in a matrix configuration having a plurality of rows and columns. Each pixel areas PA have the same structure and function, therefore one pixel area PA will be described in detail. In addition, according to an exemplary embodiment, each pixel area PA has a rectangular shape as shown in FIG. 10, but the shape of the pixel area PA should not be limited to the rectangular shape. That is, the pixel area PA may have various shapes, such as a V-shape or Z-shape.

According to an exemplary embodiment, the first substrate 100 includes a first insulating substrate 110, a first insulating layer 113, a gate line GL, a data line DL, a step-difference compensation pattern SCP, a switching element e.g., a thin film transistor (“TFT”), and a second insulating layer 115.

The gate line GL is arranged on the first insulating substrate 110 and extended in a first direction D1.

The first insulating layer 113 is formed on the first insulating substrate 110 on which the gate line GL is formed.

The data line DL is arranged on the first insulating layer 113 and cross the gate line GL. The data line DL includes a first data line portion DL1 extended in a second direction D2 that is substantially perpendicular to the first direction D1 and a second data line portion DL2 connected to the first data line portion DL1 and protruded to the first direction D1. The second data line portion DL2 is arranged adjacent to the gate line GL.

According to an exemplary embodiment, the step-difference compensation pattern SCP is arranged on the first insulating layer 113 between the gate line GL and the data line DL. The step-difference compensation pattern SCP is used to compensate for a step difference between the data line DL and the first insulating layer 113, and an upper surface of the step-difference compensation pattern SCP is arranged on a same plane as an upper surface of the data line DL. As shown in the plan view, the step-difference compensation pattern SCP is arranged in the second direction D2 in which the first data line portion DL1 is extended. Thus, the step-difference compensation pattern SCP is positioned at both sides of the gate line GL near an area where the data line DL crosses the gate line GL. The step-difference compensation pattern SCP may include an inorganic material. The inorganic material may be silicon nitride (SiNx), amorphous silicon (a-Si), or impurity-doped amorphous silicon (n+a-Si).

According to an exemplary embodiment, a thin film transistor TFT is arranged adjacent to the area where the data line DL crosses the gate line GL and includes a gate electrode GE, a semiconductor layer SM, a source electrode SE, and a drain electrode DE.

According to an exemplary embodiment, the gate electrode GE is branched from the gate line GL. The semiconductor layer SM is formed on the first insulating layer 113 to overlap with the gate electrode GE. The source electrode SE is branched from the data line DL and is overlapped with a portion of the semiconductor layer SM. The drain electrode DE is spaced apart from the source electrode SE and overlapped with a portion of the semiconductor layer SM. The semiconductor pattern SM forms a conductive channel between the source electrode SE and the drain electrode DE.

According to an exemplary embodiment, the second insulating layer 115 is arranged on the first insulating layer 113 on which the source and drain electrodes SE and DE are formed. The second insulating layer 115 is provided with a contact hole CH formed therethrough to partially expose the drain electrode DE, and a first electrode EL1, which will be described later, is connected to the drain electrode DE through the contact hole CH.

According to an exemplary embodiment, the step-difference compensation pattern SCP may be formed through a separate patterning process, or according to another exemplary embodiment, the step-difference compensation pattern SCP may be formed from the same layer as the semiconductor pattern SM. Thus, the semiconductor pattern SM and the step-difference compensation pattern SCP may be substantially simultaneously patterned, to thereby form the step-difference compensation pattern SCP without an additional process.

As further shown in FIG. 11, the second substrate 200 is arranged to face the first substrate 100. The second substrate 200 includes a second insulating substrate 210.

According to an exemplary embodiment, the bonding spacer ADS is arranged on the first substrate 100. The bonding spacer ADS maintains a distance between the first and second substrates 100 and 200 and bonds the first substrate 100 to the second substrate 200. In this exemplary embodiment, the bonding spacer ADS may be used as a barrier to divide the first substrate 100 into a plurality of areas. Since the barrier is formed between the first and second substrates 100 and 200, the barrier may divide a space between the first and second substrates 100 and 200 into a plurality of areas.

According to an exemplary embodiment, the plurality of areas divided by the bonding spacer ADS may have various shapes. Further, the bonding spacer ADS may be formed along an end portion of the pixel area PA. The bonding spacer ADS is formed in a straight line shape along the second direction D2 in which the first data line portion DL1 is extended and the bonding spacer ADS is overlapped with the first data line DL1 and the step-difference compensation pattern SCP. According to an exemplary embodiment, the bonding spacer ADS has a width greater than that of the first data line portion DL1. The bonding spacer ADS contacts other elements and the contact size between the bonding spacer ADS and the elements may change based on a pixel design and a process margin. Further, the bonding spacer ADS may be overlapped with a portion of the second data line portion DL2.

The image display part 300 is disposed between the first substrate 100 and the second substrate 200 in a space defined by the first substrate 100, the second substrate 200, and the bonding spacer ADS.

The image display part 300 includes a first electrode EL1, a second electrode EL2, and an image display layer 301 to absorb or reflect an external light, thereby displaying an image.

Referring to FIGS. 10 and 11, the first electrode EL1 is arranged on the first substrate 100 in one-to-one correspondence relationship with the pixel area PA. The first electrode EL1 is arranged on the second insulating layer 115. The first electrode EL1 includes a metal reflective material to reflect the light. The first electrode EL1 is electrically connected to the drain electrode DE through the contact hole CH formed through the second insulating layer 115.

The second electrode EL2 is formed on the second insulating substrate 210. The second electrode EL2 receives a common voltage, and the second electrode EL2 and the first electrode EL1 generates an electric field therebetween. The second electrode EL2 is formed on the second insulating substrate 210 using a transparent material.

According to an exemplary embodiment, the image display layer 301 is a liquid crystal layer 310. The liquid crystal layer 310 is controlled by the electric field to display the image. The liquid crystal layer 310 may be a cholesteric liquid crystal layer, and thus the display apparatus may be a reflective-type display apparatus. The cholesteric liquid crystal layer includes a periodical spiral structure with a constant pitch and selectively reflects the light according to the constant pitch. Therefore, the cholesteric liquid crystal layer may reflect a red light, a green light and a blue light according to its pitch. Thus, liquid crystal layers each reflecting the red light, the green light, and the blue light are respectively disposed in the areas of the image display layer 301, which are divided by the bonding spacer ADS.

According to an exemplary embodiment, when the display apparatus is the reflective-type display apparatus, the bonding spacer ADS may be formed to have a white color which has a high reflectivity with respect to the external light. In the reflective-type display apparatus, the bonding spacer ADS may cover the data line without forming an additional black matrix. In addition, since the bonding spacer ADS has the white color, brightness of the reflective-type display apparatus may increase.

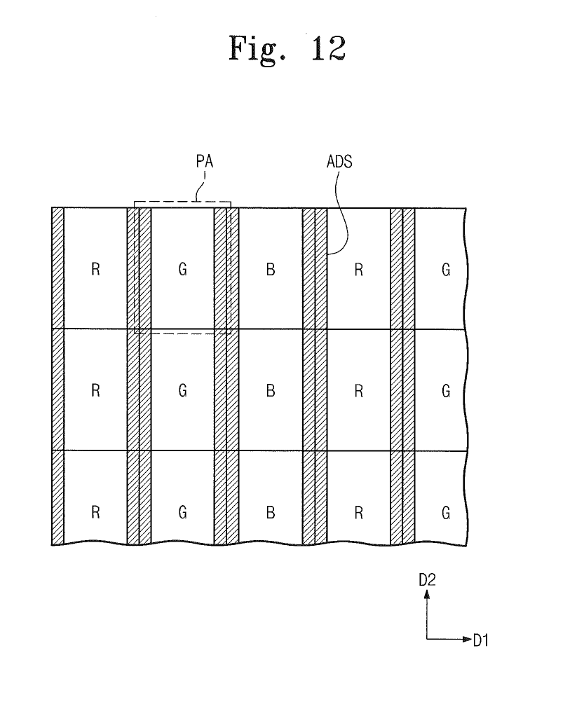

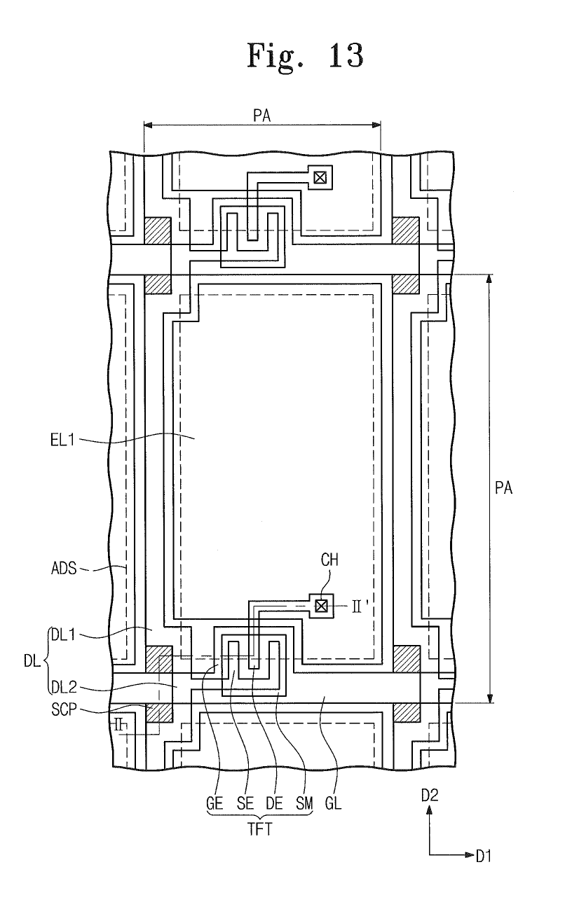

FIG. 12 is a plan view illustrating an exemplary embodiment of the pixel areas including the bonding spacer of FIG. 10.

Referring to FIG. 12, the first substrate 100 includes the pixel areas PA. The bonding spacers ADS are at the end portion of each pixel area PA. The bonding spacers ADS are extended in the second direction D2 and arranged in the first direction D1. The areas divided by the bonding spacers ADS are filled with a red-reflective cholesteric liquid crystal layer, a green-reflective cholesteric liquid crystal layer, and a blue-reflective cholesteric liquid crystal layer. As shown in FIG. 12, the bonding spacers ADS are disposed between the pixel areas PA representing different colors and not disposed between the pixel areas PA representing same colors. Thus, the pixel areas PA representing the same colors may be filled with the cholesteric liquid crystal layer having the color corresponding to the pixel areas PA representing the same colors simultaneously.

According to an exemplary embodiment, in the display apparatus, when an alignment direction of liquid crystal molecules is changed by the electric field, an amount of light transmitting through the liquid crystal layer is controlled, thereby displaying the image. Since the cholesteric liquid crystal layer displays colors, no separate color filter is required even when displaying color images.

According to an exemplary embodiment, the second data line portion DL2 is protruded to the first direction D1 in order to minimize the step difference on the surface of the first substrate 100 corresponding to the area where the bonding spacer ADS is formed. Thus, the bonding spacer ADS is not overlapped with an area where the data line DL crosses the gate line GL. Also, since the second data line portion DL2 is protruded to the first direction D1, the step difference generated between the first insulating layer 113 and the first and second data line portions DL1 and DL2 may be compensated by the step-difference compensation pattern SCP. Therefore, the first substrate 100 includes a flat surface in an area in which the bonding spacer ADS is formed, so that the leakage of the liquid crystal to the adjacent pixel areas PA may be prevented.

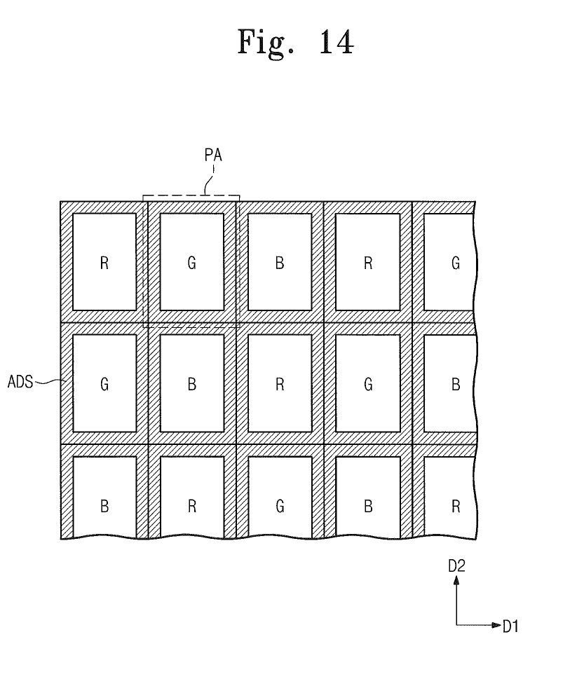

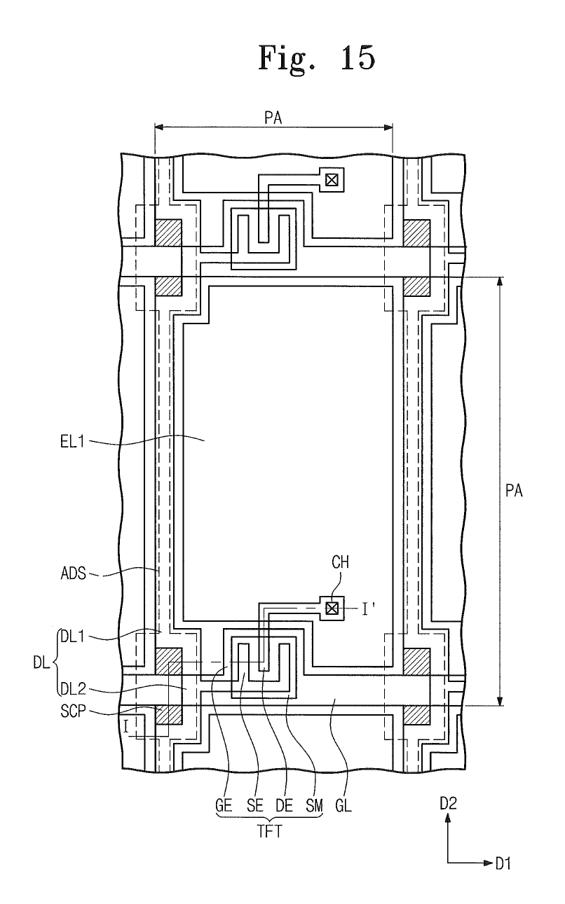

FIG. 13 is a plan view illustrating an exemplary embodiment of a display apparatus according to the present invention, and FIG. 14 is a plan view illustrating the pixel areas PA including a barrier as shown in FIG. 13. In FIGS. 13 and 14, the same reference numerals denote the same elements in FIGS. 10 and 11, and thus detailed descriptions of the same elements will be omitted.

Referring to FIGS. 13 and 14, a bonding spacer ADS is formed to surround each pixel area PA unlike the bonding spacer ADS shown in FIG. 12. That is, the bonding spacer ADS is overlapped with the data line DL and the step-difference compensation pattern SCP in the second direction D2 and overlapped with the gate line GL in the first direction D1. Therefore, a space defined by a first substrate 100, a second substrate 200, and the bonding spacer ADS is formed corresponding to each of the pixel areas PA.

According to an exemplary embodiment, the bonding spacer ADS may be formed to have a white color having a high reflectivity with respect to the external light. Although an additional black matrix is not formed, the display apparatus may cover the gate line GL and the data line DL using the bonding spacer ADS. Also, when the bonding spacer ADS has the white color, an amount of light reflected by the bonding spacer ADS increases, thereby improving the brightness of the display apparatus.

According to this exemplary embodiment, a cholesteric liquid crystal layer may be arranged in each pixel area PA to display a different color from an adjacent pixel area PA. In one exemplary embodiment, when a red-reflective cholesteric liquid crystal layer is arranged in a pixel area PA, a green-reflective cholesteric liquid crystal layer or a blue-reflective cholesteric liquid crystal layer is arranged in the pixel areas PA adjacent to the one pixel area PA in which the red-reflective cholesteric liquid crystal layer is arranged.

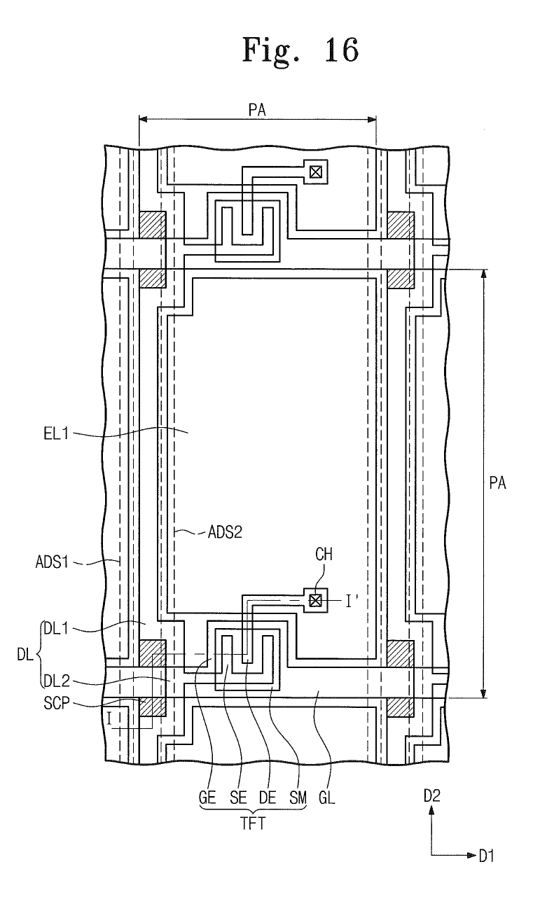

FIG. 15 is a plan view illustrating another exemplary embodiment of a display apparatus according to the present invention. In FIG. 15, the same reference numerals denote the same elements in FIGS. 10 and 11, and thus detailed descriptions of the same elements will be omitted.

Referring to FIG. 15, a bonding spacer ADS may have a similar structure as the bonding spacer ADS shown in FIG. 12, however, the bonding spacer ADS according to this exemplary embodiment includes a width less than that of the first data line portion DL1. In addition, the bonding spacer ADS includes a width greater than that of an area where the bonding spacer ADS is overlapped with the first data line portion DL1 to fully cover the step-difference compensation pattern SCP.

Therefore, according to an exemplary embodiment, the bonding spacer ADS covers a crevice that may be produced between the step-difference compensation pattern SCP and the data line DL. As a result, a first substrate 100 may be formed to have a flat surface corresponding to the area where the bonding spacer ADS is formed, thereby reducing leakage of the liquid crystal molecules to the adjacent pixel area PA.

FIG. 16 is a plan view illustrating another exemplary embodiment of a display apparatus according to the present invention. In FIG. 16, the same reference numerals denote the same elements in FIGS. 10 and 11, and thus detailed descriptions of the same elements will be omitted.

Referring to FIG. 16, according to an exemplary embodiment, a bonding spacer ADS shown may have a similar structure as the bonding spacer ADS shown in FIG. 12, however the bonding spacer ADS includes a double-wall shape. That is, the bonding spacer ADS includes a first bonding spacer ADS1 and a second bonding spacer ADS2 that are spaced apart from each other by the first data line DL1 while being adjacent to each other. The first bonding spacer ADS1 and the second bonding spacer ADS2 are extended in a second direction D2. The first and second bonding spacers ADS1 and ADS2 may be partially overlapped with the first data line portion DL1. In FIG. 16, according to an exemplary embodiment, the first and second bonding spacers ADS1 and ADS2 are not overlapped with the first data line DL1.

According to an exemplary embodiment, one of the first and second bonding spacers ADS1 and ADS2 prevents leakage of the liquid crystal molecules to adjacent pixel areas PA, the other bonding spacer ADS1 or ADS2 prevents the leakage of the liquid crystal molecules. As a result, the leakage of the liquid crystal molecules may be prevented.

As described above, according to an exemplary embodiment the image display layer 301 is a liquid crystal layer 310 according to an exemplary embodiment, however it is not limited hereto According to another exemplary embodiment, the image display layer 301 may be an electrophoretic layer 320 as described below.

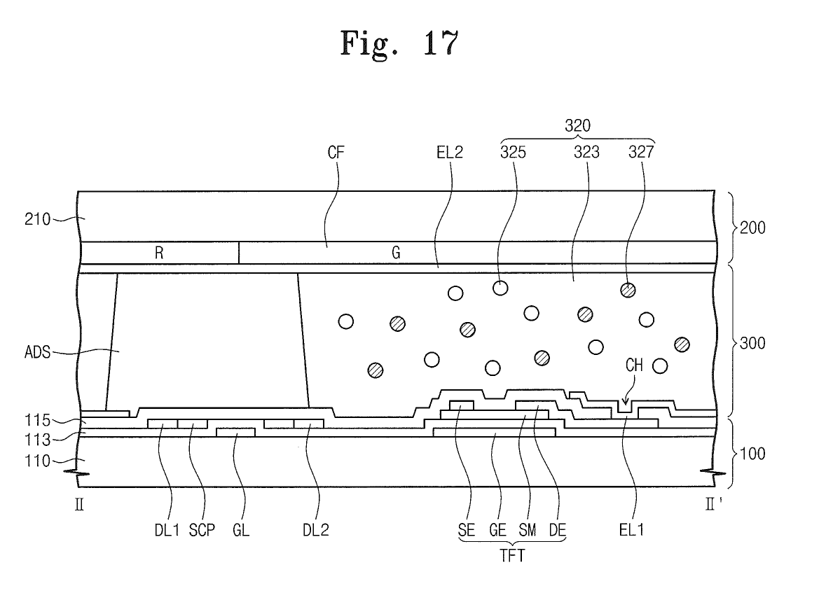

FIG. 17 is a cross-sectional view illustrating an exemplary embodiment of a display apparatus including the electrophoretic layer as the image display layer according to the present invention. FIG. 17 is a cross-sectional view corresponding to a line II-IF of FIG. 13. In FIG. 17, the same reference numerals denote the same elements in FIG. 11, and thus the detailed descriptions of the same elements will be omitted.

Referring to FIGS. 13 to 17, in this exemplary embodiment, the image display layer 301 is the electrophoretic layer 320.

According to an exemplary embodiment, the electrophoretic layer 320 includes an insulating medium 323 and charged particles 325 and 327. The insulating medium 323 corresponds to a dispersive medium in a dispersion system where the charged particles 325 and 327 are dispersed. The charged particles 325 and 327 include white charged particles 325 and non-white charged particles 327. The non-white charged particles 327 may have a black color. The white charged particles 325 and the non-white charged particles 327 are charged to have mutually opposite polarities.

According to an exemplary embodiment, the second substrate 200 includes a color filter layer CF to display colors. The color filter layer CF is disposed between the second insulating substrate 210 and the second electrode EL2. The color filter layer CF displays a red color R, a green color G, and a blue color B corresponding to each pixel area PA.

According to an exemplary embodiment, when the thin film transistor TFT is turned on in response to a driving signal applied through the gate line GL, an image signal provided through the data line DL is transmitted to the first electrode EL1 through the turned-on thin film transistor TFT. Thus, an electric field is generated between the first electrode EL1 and the second electrode EL2 to which the common voltage is applied. The charged particles 325 and 327 move according to the electric field, and thus, an external light incident to the electrophoretic layer 320 is absorbed or reflected by the charged particles 325 and 327 to display an image.

Although not shown in figures, according to another exemplary embodiment, the electrophoretic layer 320 may include a plurality of capsules. When the electrophoretic layer 320 includes the capsules, the charged particles 325 and 327 and the insulating medium 323 are provided in the capsules. According to another exemplary embodiment, when the charged particles have colors, the color filter layer CF may be omitted. Also, according to another exemplary embodiment, the electrophoretic layer 320 may include an electrophoretic emulsion. The electrophoretic emulsion includes a non-polar solvent which forms a continuous phase and a polar solvent that is dispersed by the non-polar solvent and forms a droplet controlled by the electric field generated by the first and second electrodes EL1 and EL2. The polar solvent includes dyes which are insoluble in the non-polar solvent and soluble in the polar solvent, so that the polar solvent may display a black color or a white color by the dyes. Therefore, the polar solvent may have a better mobility or cohesive force than the non-polar solvent by the electric field.

According to another exemplary embodiment, the image display layer 301 may be an electrochromic layer 330.

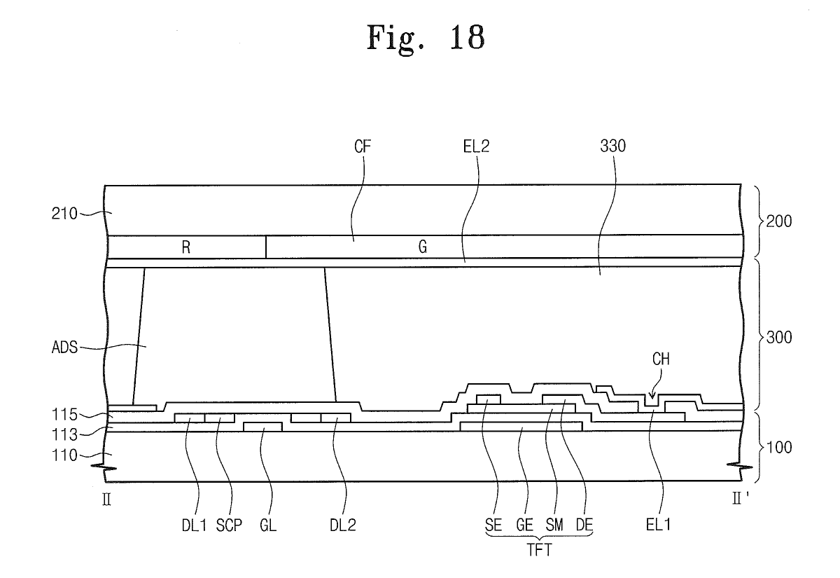

FIG. 18 is a cross-sectional view illustrating an exemplary embodiment of a display apparatus including the electrochromic layer 330 as the image display layer according to the present invention. In FIG. 18, the same reference numerals denote the same elements in FIG. 17, and thus the detailed descriptions of the same elements will be omitted.

The electrochromic layer 330 has shown different extents of oxidation reaction and reduction reaction, and a transparency of the electrochromic layer 330 is controlled by the oxidation and reduction difference. The electrochromic layer 330 displays an image by the voltage applied to the first and second electrodes EL1 and EL2.

According to an exemplary embodiment, the electrochromic layer 330 is formed with at least one inorganic compound selected from the group consisting of tungsten oxide (WO₃), molybdenum oxide (MoO₃) and iridium oxide (IrOx) or at least one organic compound selected from the group consisting of viologen, rare-earth phthalocyanine, and styryl. Also, the electrochromic layer 330 may be formed with at least one conductive polymer selected from the group including polypyrrole, polythiophene, and polyaniline.

According to another exemplary embodiment, the image display layer 301 may be an electro-wetting layer 340.

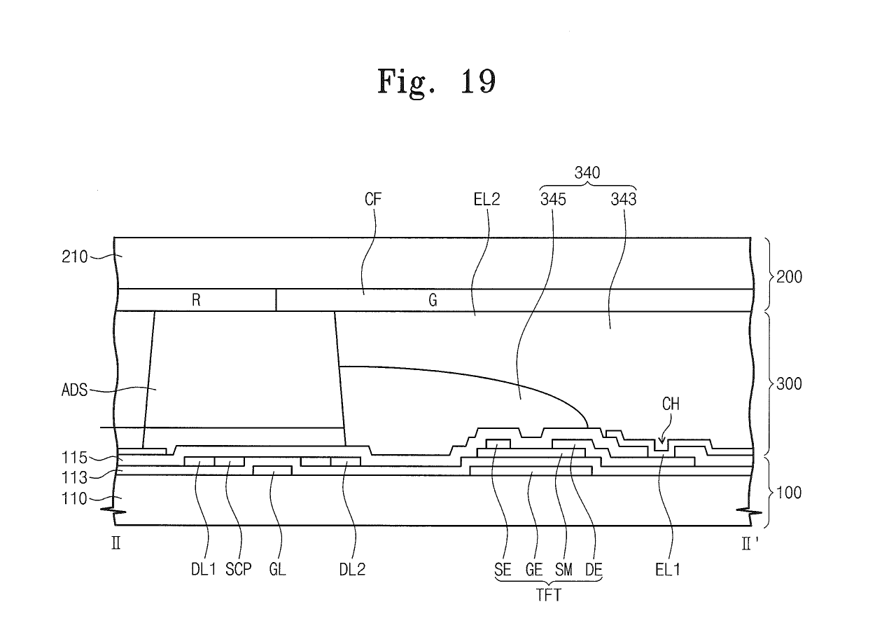

FIG. 19 is a cross-sectional view illustrating an exemplary embodiment of a display apparatus including the electro-wetting layer 340 as the image display layer 301 according to the present invention. In FIG. 19, the same reference numerals denote the same elements in FIG. 18, and thus the detailed descriptions of the same elements will be omitted. Referring to FIG. 19, the image display part 300 includes the first electrode EL1 and the electro-wetting layer 340, and the second electrode EL2 is omitted.

In the electro-wetting layer 340, an electrocapillary phenomenon occurs, in which an interfacial surface tension is changed by electric charges existing on an interface of an electrically conductive fluid to vary a contact angle. The electro-wetting is a technique which uses the electrocapillary phenomenon to vary the contact angle of the electrically conductive fluid and interfaces of the two fluids by applying the voltage to the electrically conductive fluid when the conductive fluid makes contact to a non-conductive fluid on the first electrode and controlling the surface tension of the electrically conductive fluid.

According to an exemplary embodiment, the electro-wetting layer 340 includes a first fluid 345 and a second fluid 343 that are not mixed with each other. The first fluid 345 may be a black fluid. The electro-wetting layer 340 changes the distribution of the first and second fluids 343 and 345 according to the electric field, to thereby block or transmit the external light.

According to an exemplary embodiment, the first fluid 345 and the second fluid 343 may have different electric conductivity. In one exemplary embodiment, the first fluid 345 may have the electric conductivity and the second fluid 343 may have electric insulating property. In an exemplary embodiment, the first fluid 345 is an electrolyte of which solvent is water and the second fluid 343 is oil.

According to an exemplary embodiment, when the voltage is applied to the first electrode EL1, the surface tension of the first fluid 345 is weakened and covers the entire surface of each pixel area PA, thereby displaying the black color. According to another exemplary embodiment, when the voltage is not applied to the first electrode EL1, the surface tension of the first fluid 345 becomes stronger and the first fluid 345 congregates in a certain area of each pixel area PA, to thereby transmit the light.

Although exemplary embodiments have been described, it is understood that the present invention should not be limited to these exemplary embodiments but various changes and modifications can be made by one ordinary skilled in the art within the spirit and scope of the present invention as hereinafter claimed.

For example, various exemplary embodiments of the image display layer have been described, however the image display layer should not be limited thereto. That is, an electro-fluidic layer or other types of layer may also be used as the image display layer. In addition, the exemplary embodiments of the present invention have been mainly described with reference to the reflective-type display apparatus, but the display apparatus should not be limited thereto. That is, the above-described exemplary embodiments may be applied to a transmissive-type display apparatus employing a separate light source.

What is claimed is:

1. A method of manufacturing a display apparatus, comprising:
preparing a first substrate and a second substrate;
forming a bonding spacer on the first substrate having a first height;
forming a supporting spacer on the second substrate having a second height less than the first height;
forming an image display part on one of the first substrate or the second substrate; and
coupling the first substrate and the second substrate together until an upper surface of the supporting spacer contacts with the first substrate and the second substrate is bonded to the bonding spacer.

2. The method of claim 1, wherein the forming of the bonding spacer comprises:
coating a resist on the first substrate;
pre-baking the resist at a temperature of about 80° C. to about 100° C. during about 50 seconds to about 70 seconds;
exposing the resist to a light; and
developing the resist.

3. The method of claim 2, further comprising forming a sealant along with an end portion of one of the first substrate and the second substrate prior to coupling the first and second substrates.

4. The method of claim 3, further comprising forming an inorganic layer on the second substrate to face the bonding spacer.

5. The method of claim 3, further comprising post-baking the bonding spacer and the sealant at a temperature of about 100° C. to about 140° C. during about 15 minutes to about 120 minutes after coupling the first and second substrates together.

6. The method of claim 1, wherein the forming of the supporting spacer comprises:
coating a resist on the second substrate;
pre-baking the resist at a temperature of about 80° C. to about 100° C. during about 50 seconds to about 70 seconds;
exposing the resist to a light;
developing the resist; and
post-baking the resist at a temperature of about 210° C. to about 240° C. during about 15 minutes to about 120 minutes.

7. The method of claim 1, wherein the image display part comprises an image display layer absorbing or reflecting a light to display an image, wherein the image display layer is at least one of a liquid crystal layer, an electrophoretic layer, an electro-wetting layer, or an electrochromic layer.

8. The method of claim 7, wherein the image display layer is the liquid crystal layer, and the liquid crystal layer comprises a cholesteric liquid crystal.

9. The method of claim 7, wherein one of the first substrate and the second substrate comprises a plurality of pixel areas, and the bonding spacer is a barrier formed at an end of each pixel area.

10. The method of claim 7, wherein one the first substrate and the second substrate comprises a plurality of pixel areas; and
the preparing of the first or second substrate further comprises forming switching elements in the pixel areas, respectively.

11. A display apparatus comprising:
a first substrate;
a second substrate facing the first substrate;
a bonding spacer arranged on the first substrate, wherein the bonding spacer divides the first substrate into a plurality of areas, maintains a distance between the first substrate and the second substrate, and bonds the first substrate and the second substrate; and
an image display part arranged in the plurality of areas between the first and second substrates,
wherein the first substrate comprises:
a first insulating substrate;
a gate line formed on the first insulating substrate and extending in a first direction;
a first insulating layer formed on the first insulating substrate on which the gate line is formed;
a data line formed on the first insulating layer and crossing the gate line;
a step-difference compensation pattern arranged on the first insulating layer between the gate line and the data line to compensate a step-difference between the data line and the first insulating layer; and
a switching element connected with the gate line and the data line, and the bonding spacer is overlapped with the data line and the step-difference compensation pattern.

12. The display apparatus of claim 11, wherein the data line comprises a first data line part extending in a second direction perpendicular to the first direction and a second data line part connected with the first data line part and protruded to the first direction, and the step-difference compensation pattern is formed along the second direction.

13. The display apparatus of claim 12, wherein the step-difference compensation pattern is positioned at sides of the gate line.

14. The display apparatus of claim 11, wherein the bonding spacer is overlapped with the gate line.

15. The display apparatus of claim 11, wherein the bonding spacer includes a white color.

16. The display apparatus of claim 12, wherein the bonding spacer includes a width less than the first data line part in an area where the bonding spacer is overlapped with the first data line part and the width is greater than the second data line part in an area where the bonding spacer is overlapped with the second data line part.

17. The display apparatus of claim 12, wherein the bonding spacer comprises a first bonding spacer and a second bonding spacer which are spaced apart from each other via the first data line part and extended in the second direction.

18. The display apparatus of claim 11, wherein the switching element comprises a thin film transistor comprising:
a gate electrode formed on the first insulating substrate and connected to the gate line;
a semiconductor pattern formed on the first insulating layer;
a source electrode formed on the semiconductor pattern and connected to the data line; and
a drain electrode formed on the semiconductor pattern and spaced apart from the source electrode.

19. The display apparatus of claim 18, wherein the step-difference compensation pattern is formed on a same layer as the semiconductor pattern.

20. The display apparatus of claim 19, wherein the first substrate further comprises a second insulating layer arranged on the first insulating layer on which the source electrode and the drain electrode are formed.

21. The display apparatus of claim 20, wherein the image display part comprises a first electrode formed on the second insulating layer and connected with the drain electrode, a second electrode formed on the second substrate, and an image display layer formed between the first and second electrodes, wherein the image display layer is one of a liquid crystal layer, an electrophoretic layer, an electro-wetting layer, or an electrochromic layer.

22. The display apparatus of claim 21, wherein the image display layer absorbs or reflects an external light to display an image.

23. The display apparatus of claim 22, wherein the image display layer is the liquid crystal layer, and the liquid crystal layer comprises a cholesteric liquid crystal.

24. The display apparatus of claim 11, further comprising an inorganic layer formed between the first substrate and the bonding spacer or between the second substrate and the bonding spacer.

25. The display apparatus of claim 24, further comprising an inorganic alignment layer arranged between the inorganic layer and the bonding spacer to cover the inorganic layer.

26. The display apparatus of claim 25, wherein the inorganic layer comprises silicon nitride (SiNx), and the inorganic alignment layer comprises silicon nitride (SiNx) or silicon oxide (SiOx).
